(19) United States
(12) Patent Application Publication
(10) Pub. No.: US 2026/0090275 A1
(43) Pub. Date: Mar. 26, 2026

(54) THERMAL ANNEALING OF PIEZOELECTRIC MICROELECTROMECHANICAL SYSTEMS (MEMS) STACKS

(71) Applicant: QUALCOMM Incorporated, San Diego, CA (US)

(72) Inventors: Florian LOCHNER, Taufkirchen (DE); Tobias HERO, München (DE); Christian CERANSKI, München (DE)

(21) Appl. No.: 18/896,641

(22) Filed: Sep. 25, 2024

(51) Int. Cl. H10N 30/853; H03H 3/02; H03H 9/02; H04R 17/02; H10N 30/093

(52) U.S. Cl. CPC H10N 30/853; H03H 3/02; H03H 9/02574; H04R 17/02; H10N 30/093; H03H 2003/027; H04R 2201/003

(57) ABSTRACT

Systems and techniques are provided for fabrication of piezoelectric MEMS devices to improve performance. For example, an apparatus can include a support stack including a substrate and a modified piezoelectric layer formed on or above the support stack. The modified piezoelectric layer includes a material structure modified by non-equilibrium thermal process to increase an average grain size within the material structure of the modified piezoelectric layer. In some implementations, the modified piezoelectric layer includes an aluminum nitride (AlN) crystalline lattice where at least a portion of aluminum in the AlN crystalline lattice are replaced with scandium forming aluminum scandium nitride (AlScN).

### TECHNICAL FIELD

This disclosure relates generally to acoustic transducers, and more specifically to piezoelectric microelectromechanical systems (MEMS) devices and fabrication of piezoelectric MEMS devices to improve performance.

### BACKGROUND

Micro-electro-mechanical system (MEMS) devices can be used in a variety of contexts. Piezoelectric MEMS devices, for example, can be used as transducers for converting mechanical stress into electrical signals. Electroacoustic resonators such as surface acoustic wave (SAW) and bulk acoustic wave (BAW) resonators are an example of such piezoelectric MEMs devices. MEMS acoustic transducer/sensors that convert acoustic energy into electrical signals, and/or converts an electrical signal into acoustic energy are another example of such MEMS devices.

An example of a MEMS acoustic transducer is a MEMS microphone, which converts sound pressure into an electrical voltage. Based on their transduction mechanisms, MEMS microphones can be made in various forms, such as capacitive microphones or piezoelectric microphones.

MEMS capacitive microphones and electric condenser microphones (ECMs) currently dominate the consumer electronics market for microphones. Piezoelectric MEMS microphones, however, occupy a growing portion of the consumer market, and have unique advantages compared to their capacitive counterparts. Among other things, piezoelectric MEMS microphones do not require a back plate, eliminating the squeeze film damping, which is an intrinsic noise source for capacitive MEMS microphones. In addition, piezoelectric MEMS microphones are reflow-compatible and can be mounted to a printed circuit board (PCB) using typical lead-free solder processing, which could irreparably damage typical ECMs.

Manufacturers of MEMS devices have taken a variety of approaches to improve device performance.

### SUMMARY

Aspects of the present disclosure describe devices, systems, and methods for fabrication of piezoelectric microelectromechanical system (MEMS) devices. According to at least one illustrative example, a method is provided. The method includes: forming at least one aluminum nitride (AlN) layer; modifying a crystalline lattice of the at least one AlN layer with scandium to form an aluminum scandium nitride (AlScN) layer; and performing a non-equilibrium thermal process on a device including the AlScN layer, wherein non-equilibrium thermal process increases an average grain size within a material structure of the AlScN layer.

In another example, an apparatus is provided. The apparatus includes: a support stack comprising a substrate; and a modified piezoelectric layer formed on or above the support stack, wherein the modified piezoelectric layer comprises a material structure modified by non-equilibrium thermal process to increase an average grain size within the material structure of the modified piezoelectric layer.

In another example, a non-transitory computer-readable medium is provided that has stored thereon instructions that, when executed by one or more processors, cause the one or more processors to: form at least one aluminum nitride (AlN) layer; modify a crystalline lattice of the at least one AlN layer with scandium to form an aluminum scandium nitride (AlScN) layer; and perform a non-equilibrium thermal process on a device including the AlScN layer, wherein non-equilibrium thermal process increases an average grain size within a material structure of the AlScN layer.

In accordance with another example of the present disclosure, an apparatus for is provided. The apparatus includes: means for forming at least one aluminum nitride (AlN) layer; means for modifying a crystalline lattice of the at least one AlN layer with scandium to form an aluminum scandium nitride (AlScN) layer; and means for performing a non-equilibrium thermal process on a device including the AlScN layer, wherein non-equilibrium thermal process increases an average grain size within a material structure of the AlScN layer.

In some aspects, one or more of the apparatuses described above is, is part of, or includes a mobile device (e.g., a mobile telephone or so-called “smart phone” or other mobile device), a wearable device, an extended reality device (e.g., a virtual reality (VR) device, an augmented reality (AR) device, or a mixed reality (MR) device), a personal computer, a laptop computer, a server computer, a vehicle (e.g., a computing device of a vehicle), or other device. In some aspects, an apparatus includes a camera or multiple cameras for capturing one or more images. In some aspects, the apparatus includes a display for displaying one or more images, notifications, and/or other displayable data. In some aspects, the apparatus can include one or more sensors. In some cases, the one or more sensors can be used for determining a location and/or pose of the apparatus, a state of the apparatuses, and/or for other purposes.

This summary is not intended to identify key or essential features of the claimed subject matter, nor is it intended to be used in isolation to determine the scope of the claimed subject matter. The subject matter should be understood by reference to appropriate portions of the entire specification of this patent, any or all drawings, and each claim.

The foregoing, together with other features and embodiments, will become more apparent upon referring to the following specification, claims, and accompanying drawings.

### BRIEF DESCRIPTION OF DRAWINGS

FIG. 1 illustrates aspects of a microelectromechanical system (MEMS) device stack in accordance with aspects described herein.

FIG. 2A illustrates a plan view of a piezoelectric MEMS transducer that may be used in accordance with aspects described herein.

FIG. 2B illustrates a cross-sectional view of one portion of a piezoelectric MEMS transducer that can be used in accordance with aspects described herein.

FIG. 2C illustrates aspects of a piezoelectric MEMS transducer stack in accordance with aspects described herein.

FIG. 2D illustrates aspects of a piezoelectric MEMS transducer stack in accordance with aspects described herein.

FIG. 3A illustrates aspects of a piezoelectric MEMS surface acoustic wave (SAW) resonator stack in accordance with aspects described herein.

FIG. 3B illustrates aspects of a piezoelectric MEMS SAW resonator stack in accordance with aspects described herein.

FIG. 3C illustrates aspects of a piezoelectric MEMS bulk acoustic wave (BAW) resonator stack in accordance with aspects described herein.

FIG. 4 illustrates an example structure of a modified piezoelectric layer prior to thermal annealing in accordance with aspects described herein.

FIG. 5A illustrates aspects of a rapid thermal annealing operation applied to a piezoelectric MEMS device in accordance with aspects described herein.

FIG. 5B illustrates an example structure of a modified piezoelectric layer after thermal annealing in accordance with aspects described herein.

FIG. 6A illustrates aspects of a rapid thermal annealing (RTA) operation applied to a piezoelectric MEMS device in accordance with aspects described herein.

FIG. 6B illustrates an example structure of a modified piezoelectric layer after thermal annealing in accordance with aspects described herein.

FIG. 7A illustrates a statistical summary of device performance values fabricated with and without rapid thermal annealing in accordance with aspects described herein.

FIG. 7B illustrates a statistical summary of device performance values for an additional device fabricated with and without rapid thermal annealing in accordance with aspects described herein.

FIG. 8 illustrates a method associated with RTA with modified piezoelectric devices in accordance with aspects described herein.

FIG. 9 is a block diagram of a computing device that can be used with implementations of a MEMS device having a piezoelectric layer modified and subjected to RTA in accordance with aspects described herein.

Like reference symbols in the various drawings indicate like elements.

### DETAILED DESCRIPTION

The detailed description set forth below in connection with the appended drawings is intended as a description of exemplary implementations and is not intended to represent the only implementations in which the invention may be practiced. The term “exemplary” used throughout this description means “serving as an example, instance, or illustration,” and should not necessarily be construed as preferred or advantageous over other exemplary implementations. The detailed description includes specific details for the purpose of providing a thorough understanding of the exemplary implementations. In some instances, some devices are shown in block diagram form. Drawing elements that are common among the following figures may be identified using the same reference numerals.

Piezoelectric devices operate using the piezoelectric effect, where mechanical displacement in a piezoelectric material generates an electrical response. Such devices can operate as transducers for sound waves as well as high frequency resonators. The performance of a piezoelectric device can be characterized by a “tangent delta” or “tanD” value, which represents a difference between an ideal capacitive performance of a device (e.g., where the phase difference between the voltage and current of a signal is exactly 90 degrees or pi/2) and a lossy device, where the actual performance is near 90 degrees. The tanD or tangent of the actual value provides a device characteristic that is correlated with signal to noise ratio (SNR) of a device. A tanD performance value closer to 0 reflects better performance and a lower SNR contribution from the device.

Aluminum nitride (AlN) is a piezoelectric material (a chemical compound) with a good tanD performance value. An AlN crystalline lattice with at least a portion of aluminum (e.g., aluminum atoms) in the lattice replaced with scandium according to Al(1−x)Sc(x) N where x=(0.07, 0.15, 0.20, 0.30, 0.40, etc.) is expected to have superior overall performance due to higher d31 and d33 piezoelectric coefficients. In some cases, aluminum in the AlN crystalline lattice may be modified with scandium using other processes, including, without limitation, sputtering deposition, physical vapor deposition (PVD), pulsed laser deposition (PLD), molecular beam epitaxy (MBE), chemical vapor deposition (CVD), and/or any combination thereof. Such modified piezoelectric materials, however, suffer from worse tanD performance values compared with AlN due to a material structure where lattice mismatch and additional charge traps can occur following deposition of the scandium.

According to aspects described herein, devices and methods are provided for using modified piezoelectric layers, such as AlScN, where a high temperature thermal annealing process is used to improve the tanD performance value of the materials. In some cases, the systems and methods can use high temperature annealing operations during fabrication to achieve improved device performance. The performance increase can be associated with larger average grain sizes within the structure of the modified piezoelectric material, where Rapid Thermal Annealing (RTA) (or other non-equilibrium thermal process) can result in a majority of grains in the material structure merging or partially merging.

Additional details associated with such device structures and improved device performance are provided below with respect to the figures.

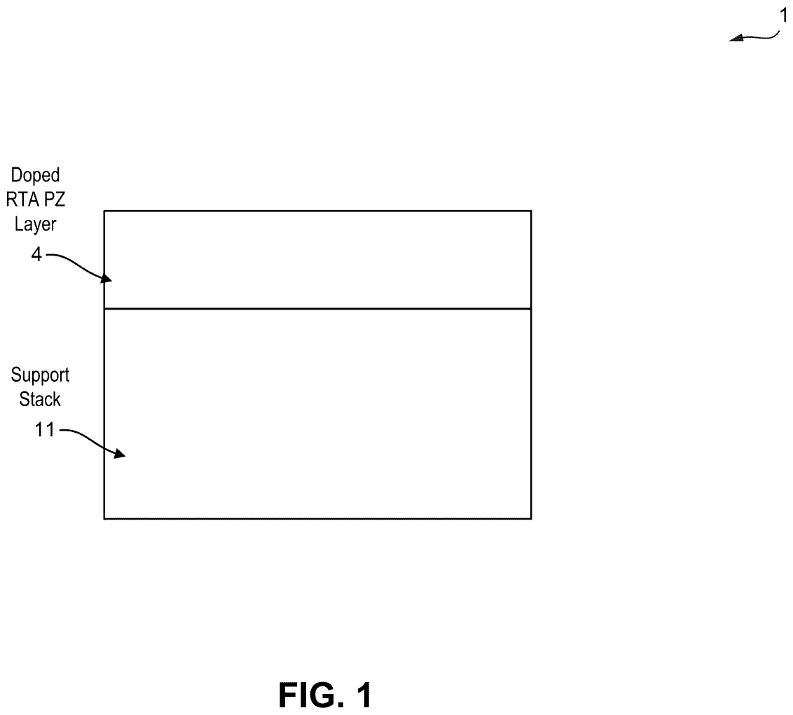

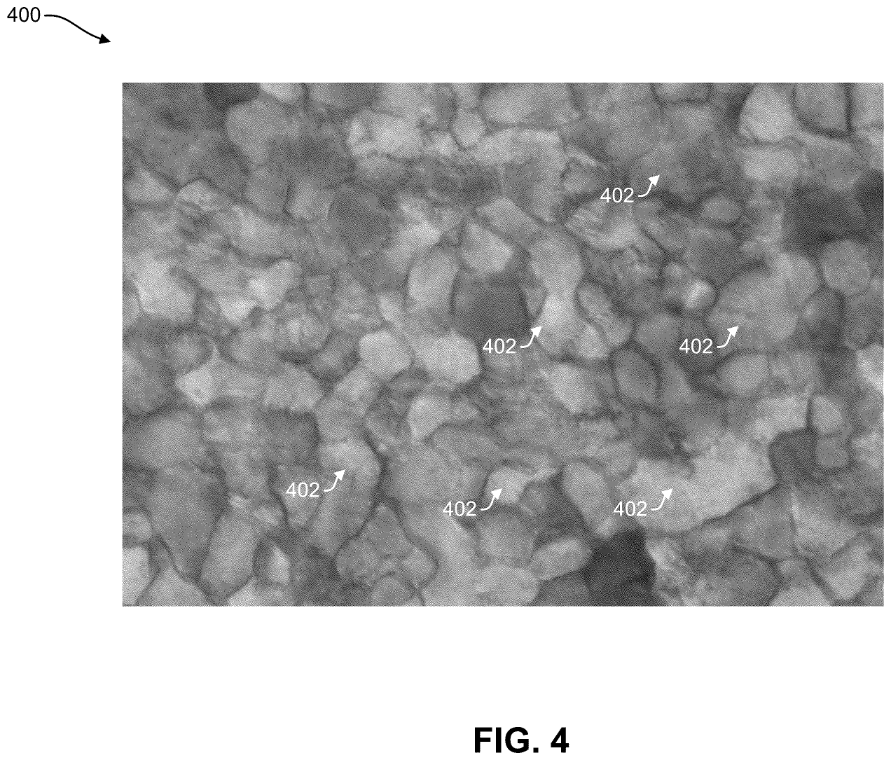

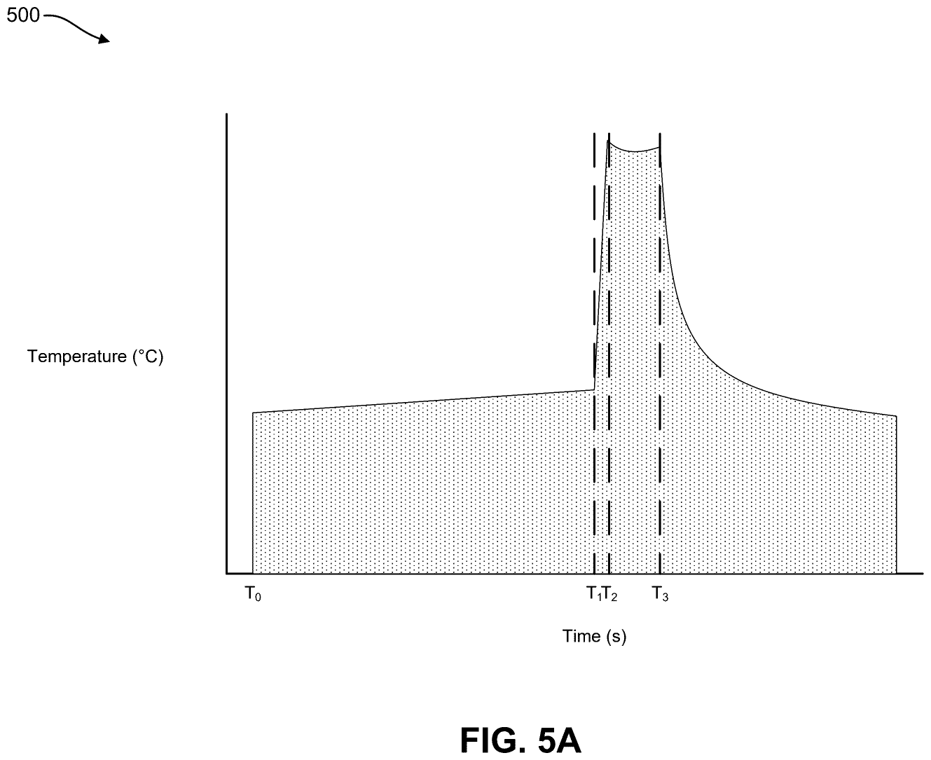

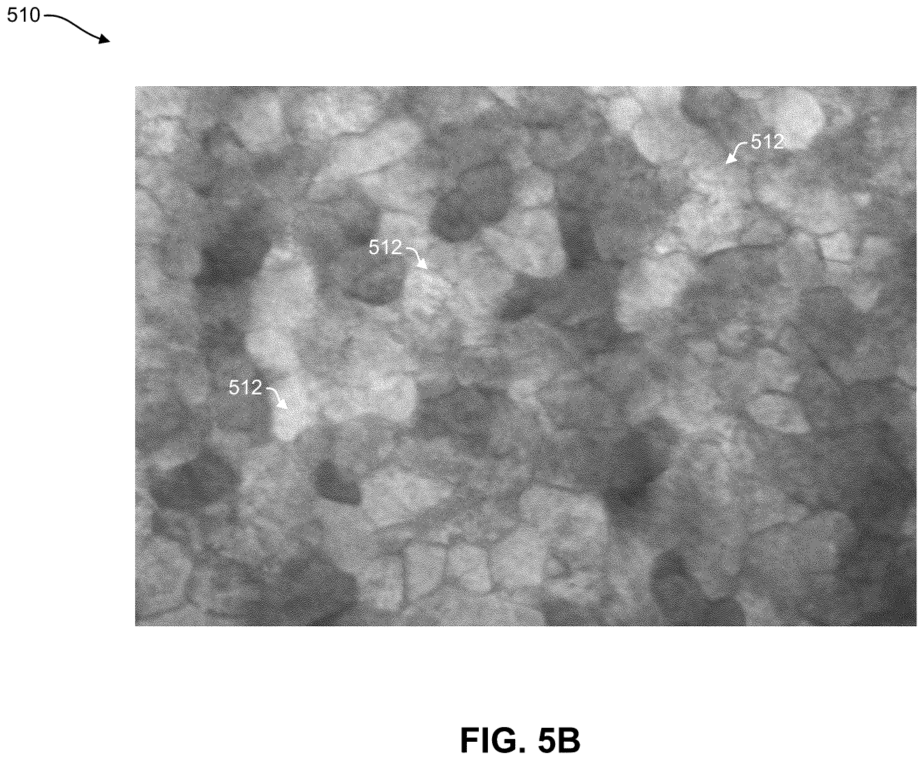

FIG. 1 illustrates aspects of a microelectromechanical system (MEMS) device stack 1 in accordance with aspects described herein. As described in FIG. 1, the MEMS device stack 1 comprises a support stack 11. As one example, the support stack 11 comprises a silicon substrate. In various implementations, alternate materials or combinations of additional materials and/or alternate materials can be used in the support stack 11. The MEMS device stack 1 further includes at least one modified piezoelectric (PZ) layer that has been subjected to a non-equilibrium thermal process. Example non-equilibrium thermal processes may include, without limitation, application of excimer laser pulses, rastering a focused beam (e.g., an electron beam, a laser beam) across a MEMS device stack 1, broad area optical illumination, rapid thermal annealing (RTA), and/or any combination thereof. For the purposes of illustration, a MEMS device stack 1 that has undergone RTA will be discussed with respect to the examples of FIG. RTA (e.g., a modified RTA PZ layer 4) formed on or above the support stack. As indicated above, RTA can modify (e.g., increase the size of) a majority of the grains in a structure formed by operations to replace a percentage of one species of atoms in a crystalline lattice with another species of atoms. Additional details of example RTA operations and material structures associated with such RTA operations used to fabricate the modified RTA PZ layer 4 are described below in the context of FIGS. 4, 5A-B, and 6A-B. Various additional aspects will be apparent in the context of the examples discussed below. The resulting modified RTA PZ layer 4 can thus comprise a material structure modified by RTA to increase an average grain size within the material structure of the modified piezoelectric layer.

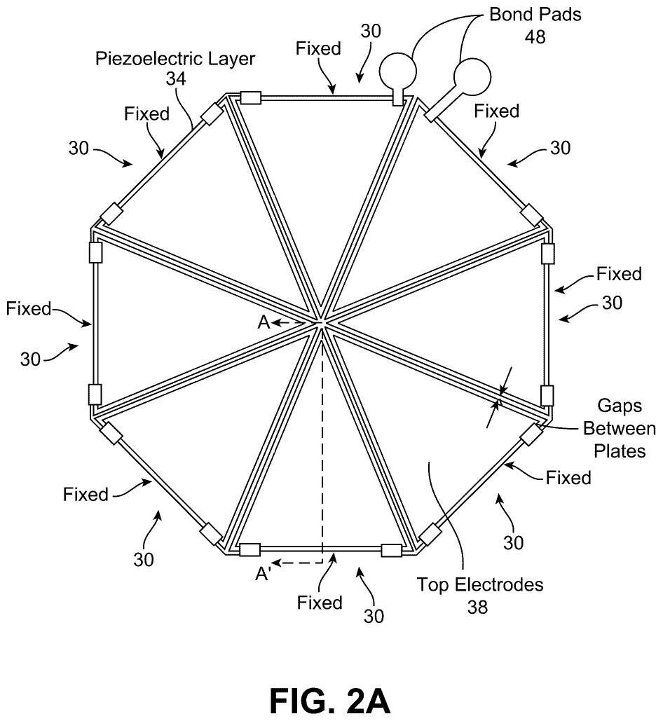

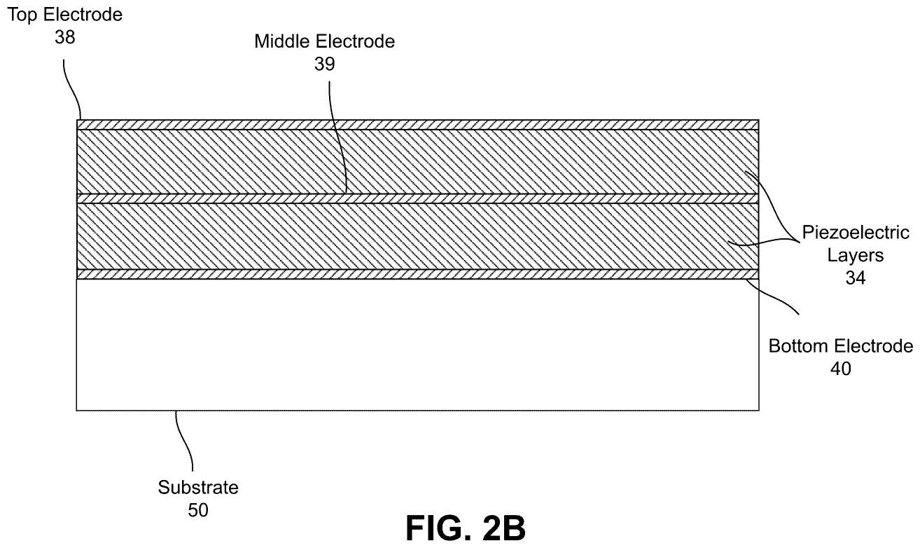

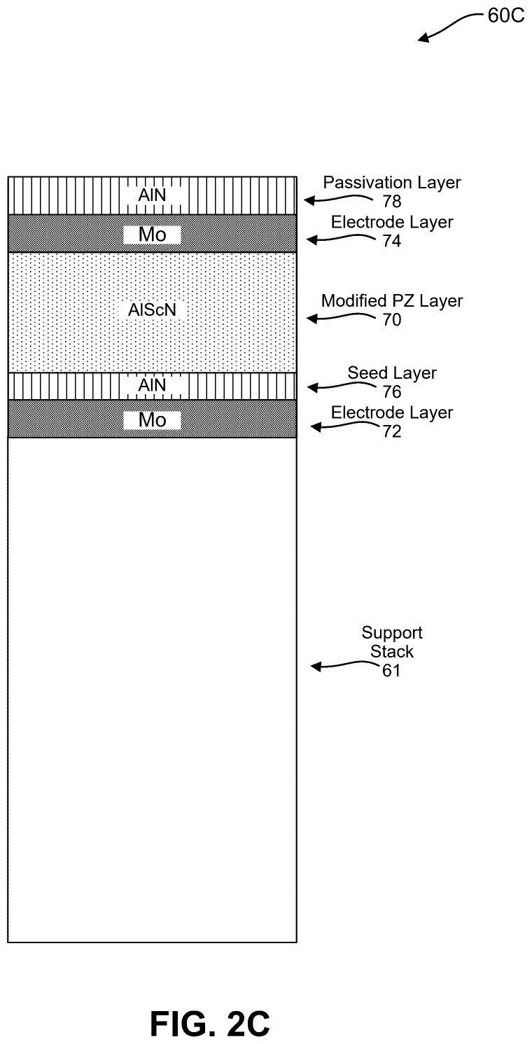

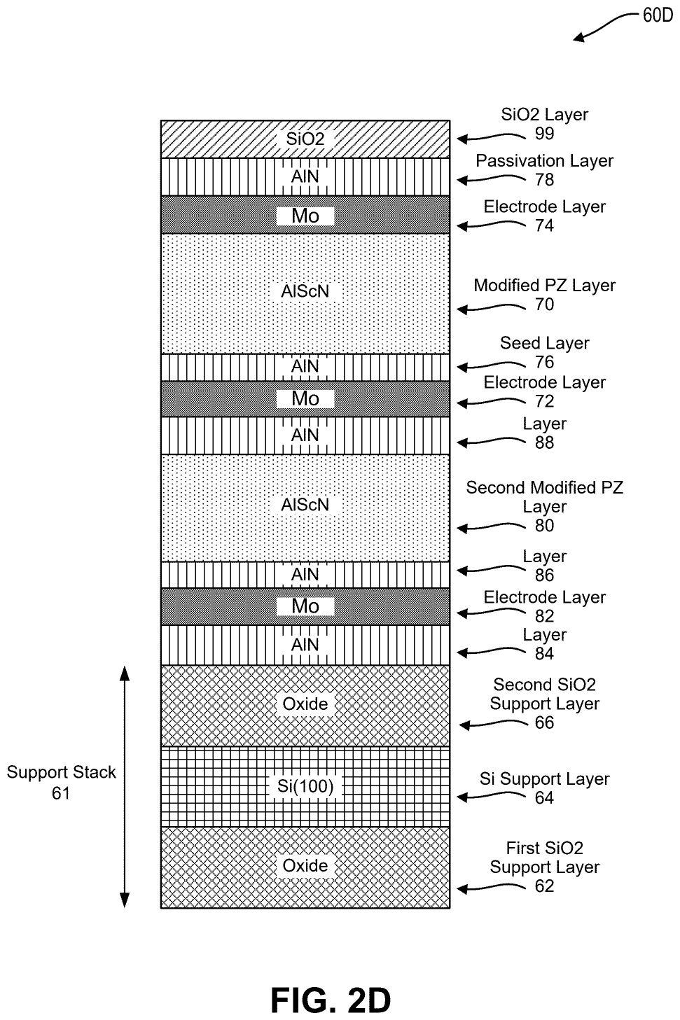

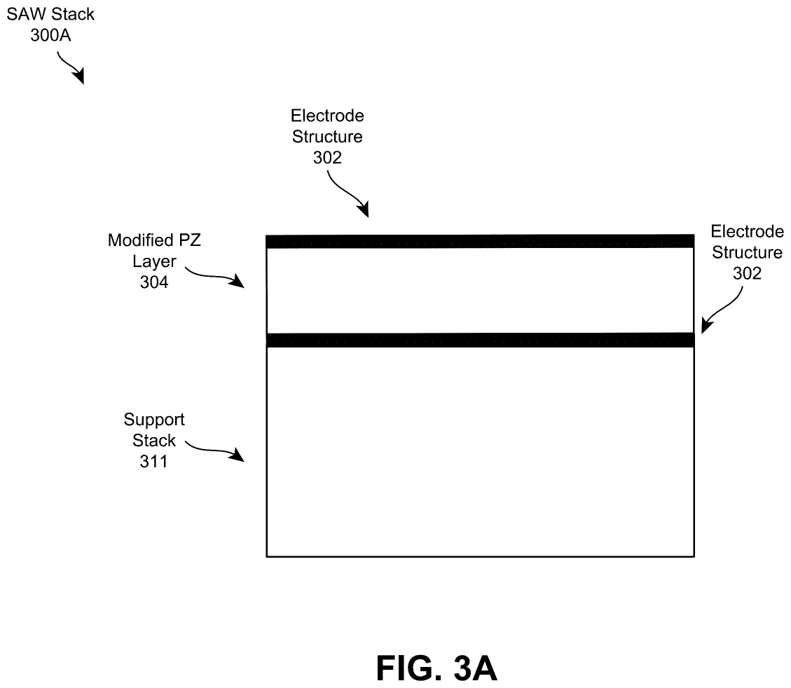

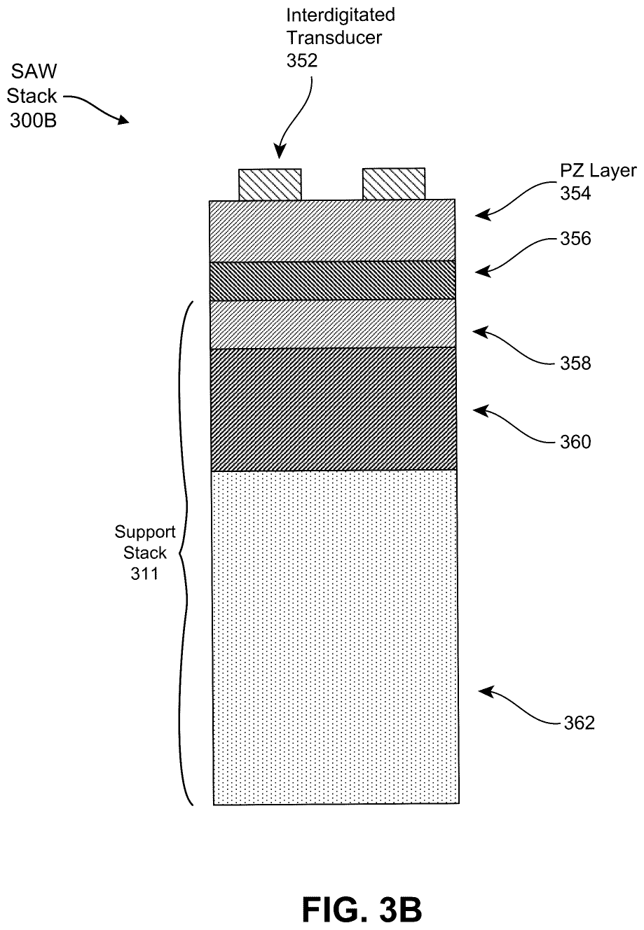

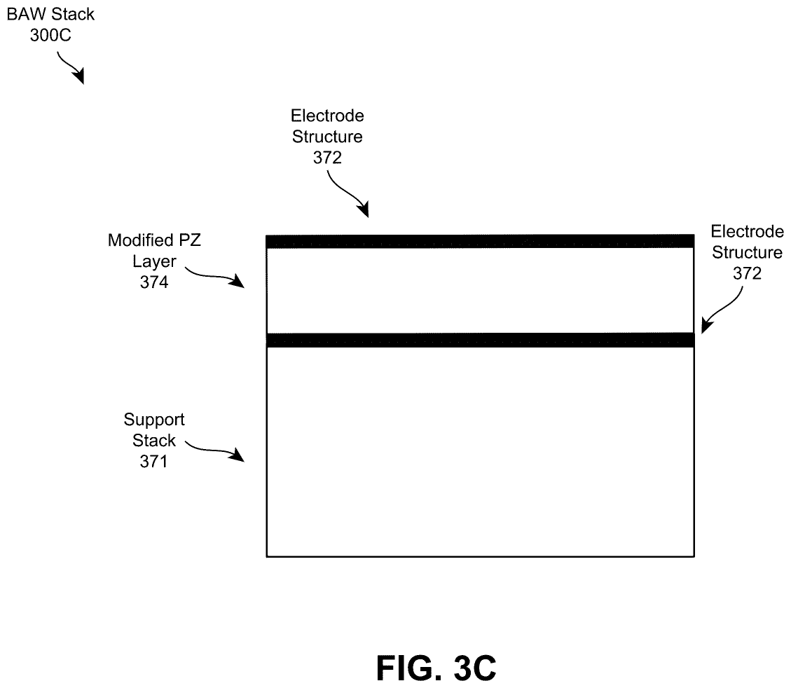

Such a modification can reduce the contribution of a MEMS device that includes the MEMS device stack 1 by lowering the overall SNR added to a signal generated or modified using the MEMS device. Such an improvement can be characterized by a reduction in the tanD performance value of the MEMS device stack 1 or an associated MEMS device that includes the MEMS device stack 1. Such MEMS devices can include acoustic MEMS transducers such as MEMS microphones or speakers that can be implemented as described in FIGS. 2A-2D below. Such MEMS devices can also include MEMS resonators such as the surface acoustic wave (SAW) MEMS resonators described in FIG. 3A and FIG. 3B below. In both such devices, electrical signals generated or modified by the associated MEMS device has improved device performance due to the use of RTA on the PZ layer of the MEMS device stack to reduce the noise added to an associated signal.

FIG. 2A illustrates a plan view of a piezoelectric MEMS acoustic transducer that may be used in accordance with aspects described herein. FIG. 2A schematically shows a plan view of a piezoelectric MEMS acoustic transducer that can be implemented using a modified RTA PZ layer (e.g., the modified RTA PZ layer 4) using a MEMS device stack similar to the MEMS device stack 1 described above or the MEMS device stack implementations detailed below. The transducer of FIG. 2A is implemented using eight MEMS cantilevers (e.g., also known as “sense arms”, “sense members”, “beams”, or “cantilevered beams” as part of one or more acoustic layers of a device) formed as piezoelectric triangular cantilevers 30. These members together can form an octagonal MEMS transducer that can be used to implement a microphone (e.g., with an associated acoustic port) or a motion sensor (e.g., without an associated acoustic port).

In FIG. 2A, each cantilever 30 has a piezoelectric structure formed in a piezoelectric layer 34, with the structure of each of the eight cantilevers 30 having an associated fixed end and an associated central end. The central ends of each cantilever 30 in FIG. 2A meet near a center, with edges of each cantilever 30 separated from adjacent cantilevers by gaps between the cantilevers 30, as illustrated. During operation, the fixed ends remain stationary, and pressure from acoustic signals (e.g., from an acoustic port of a MEMS chip configured as an acoustic transceiver) incident on the cantilevers 30 causes a pressure differential, which causes the cantilevers 30 to deflect in and out (e.g., via a slight rotation around the fixed end). The deflection causes an electrical signal from the top electrodes 38 and/or the middle electrodes 40 (see FIG. 2B) which creates the electrical signal that can be amplified by an analog front end and passed to processing circuitry as an audio signal. Such layers operate as acoustic layers converting acoustic energy into electrical signals during functional operation.

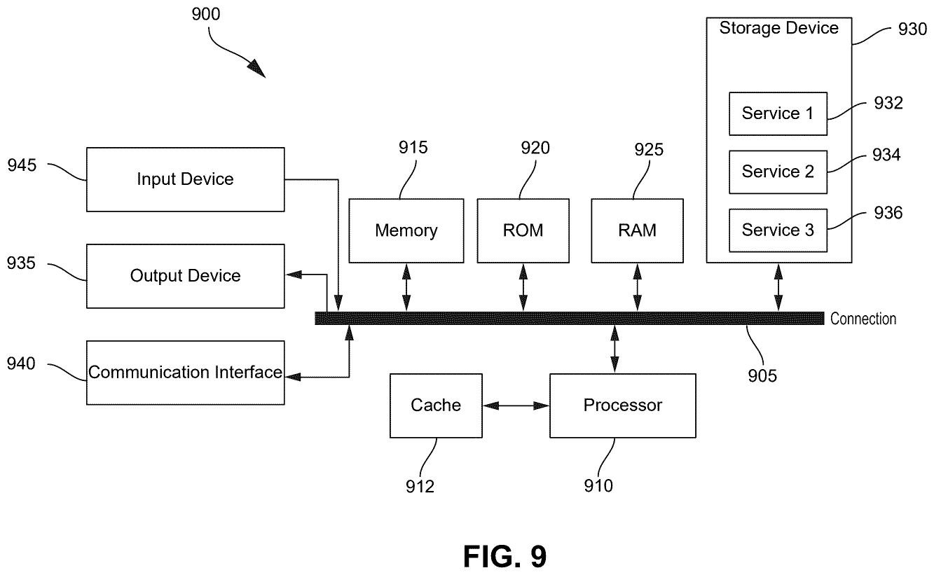

Each cantilever 30 is positioned with sides adjacent to sides of another of the cantilevered beams separated by the gap between the cantilevers. The position of the eight cantilevers 30 with the gaps creates a symmetrical polygon shape bounded by the fixed bases around the outside of the symmetrical polygon (e.g., an octagon, with one exterior side for each of the cantilever 30). In other aspects, other shapes can be used. In other implementations, MEMS acoustic transducers can include cantilevered beams with different beam shapes for the same transducer, so long as the fixed exterior edges form an enclosed transducer that separates air on one side (e.g., a pocket side) from air on another side (e.g., an acoustic port side) using the cantilevered beams (e.g., the cantilevers 30) and gaps between the beams. In some examples, a cavity (e.g., a pocket) may be included in a substrate layer (e.g., substrate 50 of FIG. 2B). The separation allows the pressure difference between the sides of the MEMS transducer to apply force to the beams and generate a signal that can be communicated to an analog front end and then to additional processing circuitry via the bond pads 48. Similarly, an electrical signal provided from transmit circuitry can cause the cantilevers 30 to deflect, generating an acoustic signal. Support and/or control circuitry such as the circuitry of the computing system 900 of FIG. 9 can be used to control or process such signals.

As illustrated in FIG. 2A, the cantilevers 30 have an associated length, determined by the line segment from the tip of the central end that is perpendicular to the fixed extreme end of the fixed end. The line segment extends from the fixed end at the substrate to the tip of the central end. As described above, when sound vibrations are present at a surface of the deflection beams, the cantilevered beams will move due to the pressure (e.g., z direction movement in and out of the x-y plane illustrated in FIG. 2A. The movement in and out of this plane is referred to herein as vertical deflection. The deflection at the fixed end will be less than the deflection at the central end, with the amount of deflection increasing along the distance of the line segment away from the substrate toward the tip of the central end. The electrodes that generate the electrical signals at the bond pads 48 in response to the acoustic vibrations on the cantilevers 30 can add rigidity to the cantilever 30, and so in some implementations, placement of the top electrodes 38 can be limited to a space approximately two-thirds of the line segment distance from the fixed attachment to the substrate at the fixed end towards the tip of the central end (e.g., limited to a fixed end). In some implementations, an electrode layer can cover a surface or x-y plane cross section of the entire illustrated fixed end of each of the cantilevered beams. In other implementations, smaller electrode shapes can be used in a portion of the fixed end of each of the cantilevers 30. In some aspects, the central end of each of the cantilevered beams does not include electrode layers. In some aspects, the electrode layers do not extend to the tip of the central end (e.g., the free movement end) of each cantilever 30 to avoid sensing free end movement in the deflection end (e.g., where the signal which is proportional to the stress in the cantilever) is lower.

FIG. 2B illustrates a cross-sectional view of one portion of the MEMS acoustic transducer of FIG. 2A in accordance with aspects described herein. FIG. 2B shows an example cross-sectional view of one of the cantilevers 30. Other aspects of a piezoelectric MEMS acoustic transducer may use more or fewer cantilevers 30. Accordingly, as with other features, discussion of eight cantilevers 30 is for illustrative purposes only. The triangular cantilevers 30 shown in FIG. 2B can be fixed at their respective bases and are configured to freely move around their fixed ends as part of acoustic layer operation in response to incoming/incident sound pressure (e.g., an acoustic wave). Triangular cantilevers 30 can provide a benefit over rectangular cantilevers as the triangular cantilevers can be more simply configured to form a gap controlling geometry separating an acoustic port on one side of the cantilevers of the piezoelectric MEMS acoustic transducer from an air pocket on the other side of the cantilevers. Specifically, when the cantilevers 30 bend up or down due to either sound pressure or residual stress, the gaps between adjacent cantilevers 30 typically remain relatively small and uniform in the example symmetrical shapes with fixed ends using the triangular cantilevers 30.

In some cases, the top electrodes 38 are electrically connected in series to achieve the desired capacitance and sensitivity values. In addition to the top electrodes 38, the rest of the cantilever 30 also may be covered by metal to maintain certain mechanical strength of the structure. For example, in some implementations, the middle electrodes 39 may be covered in metal. In some cases, the middle electrodes 39 may not contribute to the electrical signal of the microphone output. In some aspects, a MEMS acoustic transducer can include cantilevers 30 without middle electrodes 39.

As described above, as a cantilever 30 bends or flexes around the fixed end as part of acoustic layer operation, the top electrodes 38 and/or the middle electrodes 39 generate an electrical signal. The electrical signal from an upward flex (e.g., relative to the illustrated positioning in FIG. 2B) will be inverted compared with the signal of a downward flex. In some implementations, the signal from each cantilever 30 of a piezoelectric MEMS acoustic transducer can be connected to the same signal path so that the electrical signals from each cantilever 30 are combined (e.g., shared bond pads 48). In other aspects, each cantilever 30 may have a separate signal path, allowing the signal from each cantilever 30 to be processed separately. In some aspects, groups of cantilevers 30 can be connected in different combinations. In some aspects, switching circuitry or groups of switches can be used to reconfigure the connections between multiple cantilevers 30 to provide different characteristics for different operating modes, such as transmit and receive modes.

In one aspect, adjacent cantilevers 30 can be connected to separate electrical paths, such that every other cantilever 30 has a shared path. The electrical connections in such a configuration can be flipped to create a differential signal. Such an aspect can operate such that when an acoustic signal incident on a piezoelectric MEMS acoustic transducer causes all the cantilevers 30 to flex upward, half of the cantilevers 30 create a positive signal, and half the cantilevers 30 create a negative signal. The two separate signals can then be connected to opposite inverting and non-inverting ends of an amplifier of an analog front end. Similarly, when the same acoustic vibration causes the cantilevers 30 to flex downward, the signals of the two groups will flip polarity, providing for a differential electrical signal from the piezoelectric MEMS acoustic transducer.

Alternatively, rather than alternating cantilevers 30 within a single piezoelectric MEMS transducer to create a differential signal, identical MEMS transducers can be placed across a shared acoustic port with the connections to the amplifier of an analog front-end reversed and coupled to different inverting and non-inverting inputs of a differential amplifier of the analog front-end to create the differential signal using multiple piezoelectric MEMS transducers.

The cantilever 30 can be fabricated by one or multiple layers of piezoelectric material sandwiched by top electrodes 38 and bottom edge electrodes 40. FIG. 2B schematically shows an example of this structure. The piezoelectric layers 34 can be made using piezoelectric materials used in MEMS devices, such as one or more of aluminum nitride (AlN), aluminum scandium nitride (AlScN), zinc oxide (ZnO), or lead zirconate titanate (PZT). In some examples, the edge electrodes 38 and/or central electrodes 40 can be made using metal materials used in MEMS devices, such as one or more of molybdenum (Mo), platinum (Pt), nickel (Ni) and aluminum (Al), and/or any combination thereof. In some cases, top electrodes 38, middle electrodes 39, and/or bottom electrodes 40 can be formed from a non-metal, such as doped polysilicon. In some implementations, the top electrodes 38 may cover only a portion of the cantilever 30, (e.g., from the fixed end to about one third of the cantilever 30), in such cases where these areas generate electrical energy more efficiently within the piezoelectric layer 34 than the areas near the central end (e.g., the free movement end) of each cantilever 30. Specifically, high stress concentration in areas near the fixed end induced by the incoming sound pressure is converted into an electrical signal by direct piezoelectric effect.

FIG. 2C illustrates aspects of a piezoelectric MEMS transducer stack 60C in accordance with aspects described herein. The piezoelectric MEMS transducer stack 60C can be considered an implementation of the MEMS device stack 1, with implementation details specific to an acoustic transducer using the cantilever(s) 30 described in FIGS. 2A and 2B above. In the implementation of the piezoelectric MEMS transducer stack 60C, the modified RTA PZ layer 4 of FIG. 1 can include the modified PZ layer 70. In some cases, the support stack 61 can be similar to and perform similar functions to the support stack 11 of FIG. 1. As shown in FIG. 2C, the MEMS stack 60C can include additional layers used to implement the support stack 60C. For example, the additional layers of the MEMs stack 60C may include, without limitation, top and bottom electrode layers 74, 72, AlN seed layer 76, and an AlN passivation layer 78. In some cases, the AlN seed layer 76 can be a seed layer which is intended to force a dedicated crystallographic growth direction in the subsequent PZ layer 70.

FIG. 2D illustrates additional aspects of a piezoelectric MEMS transducer stack 60D in accordance with aspects described herein. The piezoelectric MEMS transducer stack 60D has a similar structure to the MEMS transducer stack 60C, but includes a second modified PZ layer 80, additional layers around the second modified PZ layer 80, and implementation details for one aspect of the support stack 61. As illustrated, in addition to the layers 70-78 shown in FIG. 2C, the MEMS transducer stack 60D of FIG. 2D further includes a first SiO2 layer 62 of the support stack 61, a silicon (e.g., Si(100)) support layer 64 formed on or above the first SiO2 support layer 62 in the support stack 61, and a second SiO2 support layer 66 formed on or above the Si support layer 64. The second modified PZ layer 80 is formed between the modified PZ layer 70 and the support stack 61, along with AlN layers 84, 86, and 88, and an additional electrode layer 82. The MEMS stack 60D is thus similar to FIG. 2B, with top, middle, and bottom electrode layers 74, 72, and 82, surrounding two piezoelectric layers (e.g., the modified PZ layer 70 and second modified PZ layer 80 similar to the piezoelectric layers 34.) FIG. 3A illustrates aspects of a piezoelectric MEMS surface acoustic wave (SAW) resonator stack 300A in accordance with aspects described herein. FIG. 3A is a diagram of a cross section from an example of an electroacoustic device. The electroacoustic device including the SAW stack 300A may be configured as or be a portion of a resonator. In certain descriptions herein, the SAW stack 300A may be part of a SAW resonator or a thin film surface acoustic wave (TF-SAW) resonator. The SAW stack 300A includes an interdigitated transducer (IDT), which is an electrode structure 302 in a metallization layer, on the surface of a piezoelectric layer 304. The piezoelectric layer 304 comprises a modified RTA PZ material similar to the material of the modified RTA PZ layer 4 of FIG. 1 described above. The electrode structure 302 generally includes first and second comb shaped electrode structures (conductive and generally metallic) with electrode fingers extending from two busbars towards each other arranged in an interlocking manner in between two busbars (e.g., arranged in an interdigitated manner). An electrical signal excited in the electrode structure 302 (e.g., applying an AC voltage) is transformed into an acoustic wave that propagates through the piezoelectric layer 304. The acoustic wave is transformed back into an electrical signal in the electrode structure 302 and provided as an output. In many applications, the piezoelectric layer 304 has a particular crystal orientation such that when the electrode structure 302 is arranged relative to the crystal orientation of the piezoelectric layer 304, the acoustic wave mainly propagates in a direction perpendicular to the direction of the fingers (e.g., parallel to the busbars).

In FIG. 3A, the SAW stack 300A is illustrated by a simplified layer stack including a piezoelectric layer 304 with an electrode structure 302 disposed on the piezoelectric layer 304. The electrode structure 302 is conductive and generally formed from metallic materials. The piezoelectric material may be formed from a modified AlN crystalline lattice in which a percentage of aluminum (e.g., aluminum atoms) in the AlN crystalline lattice are replaced by a different material (e.g., scandium). In some cases, aluminum in the AlN crystalline lattice may be modified with scandium using other processes, including, without limitation, sputtering deposition, physical vapor deposition (PVD), pulsed laser deposition (PLD), molecular beam epitaxy (MBE), chemical vapor deposition (CVD), and/or any combination thereof. The SAW stack 300A is further illustrated with a support stack 311. Additional details of support stack 311 are described in FIG. 3B below. It should be appreciated that more complicated layer stacks including layers of various materials may be possible within the SAW stack 300A. In some implementations, the piezoelectric layer 304 may be extended with multiple interconnected electrode structures disposed thereon to form a multi-resonator filter or to provide multiple filters. While not illustrated, when provided as an integrated circuit component, a cap layer may be provided over the electrode structure 302. The cap layer is applied so that a cavity is formed between the electrode structure 302 and an under surface of the cap layer. Electrical vias or bumps that allow the component to be electrically connected to connections on a substrate (e.g., via flip-chip or other techniques) may also be included.

FIG. 3B illustrates a device layer stack 300B for an electroacoustic device in accordance with aspects described herein. The device layer stack 300B includes a silicon (Si) substrate 362 as a base material substrate for the device layer stack 300B. As indicated above, using a Si substrate compatible with silicon wafer as carrier (SMR) fabrication processes improves device desirability by providing a high-quality manufacturing ecosystem which can mitigate decreased performance characteristics compared to devices with higher manufacturing costs (e.g., sapphire or diamond substrates, etc.). The use of silicon SMR devices can provide low-cost devices with acceptable performance for many applications, making devices in accordance with aspects described herein preferable to higher performance devices with higher associated costs, so long as basic performance criteria are met. The device layer stack 300B further includes mirror layer(s) 360.

The device layer stack 300B further includes piezoelectric layer 354, electrode layer 356, silicon dioxide (SiO2) layer 358 and an electrode layer including IDT 352. The IDT 352 is formed in a metallization layer on or above the piezoelectric layer 354. The piezoelectric layer 354 is formed on or above a SiO2 layer 358 and an electrode layer 356. The SiO2 layer 358 is an optional layer that is included to store energy and improve resonance characteristics along with the electrode layer 356. During operation, opposite electrical signals are provided on adjacent fingers (e.g., shown as cross sections of the adjacent fingers of the IDT 352) creating an electrical field through the piezoelectric layer 354 which excites the associated stress in the material of the piezoelectric layer 354 resulting in material displacement and acoustic waves within the device layer stack 300B. The presence of the electrode layer 356 shapes the electrical field and associated acoustic wave, stopping the electrical field from extending into the substrate. Part of the energy from the associated acoustic waves is stored within the electrode layer and the SiO2 layer 358, further shaping and tuning device resonance performance and frequencies. The SiO2 layer 358 can be adjusted or omitted as part of the selection of device performance and frequency (e.g., resonance) selection.

In both the SAW stack 300A and acoustic transducer stack examples above, the piezoelectric layer is implemented using a modified piezoelectric layer (e.g., AlScN) which has been subjected to a non-equilibrium thermal process to improve device performance. In some cases, subjecting the modified piezoelectric layer to the non-equilibrium thermal process may improve device performance by reducing a tanD performance metric and reducing associated noise added to a device implementing the associated piezoelectric layer.

FIG. 3C illustrates aspects of a piezoelectric MEMS bulk acoustic wave (BAW) resonator stack 300C in accordance with aspects described herein. FIG. 3C is a diagram of a cross section from an example of an electroacoustic device. The electroacoustic device including the BAW stack 300C may be configured as or be a portion of a resonator. In certain descriptions herein, the BAW stack 300C may be part of a solidly mounted resonator (SMR) BAW resonator or a thin film bulk acoustic wave (FBAR) resonator. The BAW stack 300C includes an electrode structure 372 in a metallization layer, on the surface of a piezoelectric layer 374. The piezoelectric layer 374 comprises a modified RTA PZ material similar to the material of the modified RTA PZ layer 4 of FIG. 1 described above. An electrical signal excited in the electrode structure 302 (e.g., applying an AC voltage) is transformed into an acoustic wave that propagates through the piezoelectric layer 374 toward the support stack 371. The acoustic wave is transformed back into an electrical signal in the electrode structure 372 and provided as an output. In many applications, the piezoelectric layer 374 has a particular crystal orientation such that when the electrode structure 372 is arranged relative to the crystal orientation of the piezoelectric layer 374, the acoustic wave mainly propagates in a direction through the bulk of the piezoelectric layer 374.

In FIG. 3C, the BAW stack 300C is illustrated by a simplified layer stack including a piezoelectric layer 374 with an electrode structure 372 disposed on the piezoelectric layer 374. The electrode structure 372 is conductive and generally formed from metallic materials. The piezoelectric material may be formed from a modified AlN crystalline lattice in which a percentage of aluminum (e.g., aluminum atoms) in the AlN crystalline lattice are replaced by a different material (e.g., scandium). In some cases, aluminum in the AlN crystalline lattice may be modified with scandium using other processes, including, without limitation, sputtering deposition, physical vapor deposition (PVD), pulsed laser deposition (PLD), molecular beam epitaxy (MBE), chemical vapor deposition (CVD), and/or any combination thereof. The SAW stack 300C is further illustrated with a support stack 371. In some cases, the support stack 371 may include one or more acoustic mirrors (not shown). For example, a support stack 371 for an SMR BAW device may include one or more acoustic mirrors in the support stack 371 can provide acoustic isolation between the piezoelectric layer 374 and other layers included in the BAW stack 300C. In some implementations, the support stack 371 may include an air cavity that separates the piezoelectric layer 374 from other structural elements of the resonator stack. In some aspects, the air cavity included in the support stack may be included in one or more SiO2 layers included in the support stack 371, one or more Si layers (e.g., Si(100)), one or more additional piezoelectric layers, and/or any combination thereof.

It should be appreciated that more complicated layer stacks including layers of various materials may be possible within the BAW stack 300C. Electrical vias or bumps that allow the component to be electrically connected to connections on a substrate (e.g., via flip-chip or other techniques) may also be included.

In the BAW stack 300C example above, the piezoelectric layer can be implemented using a modified piezoelectric layer (e.g., AlScN) which has been subjected to a non-equilibrium thermal process to improve device performance. In some cases, subjecting the modified piezoelectric layer to the non-equilibrium thermal process may improve device performance by reducing a tanD performance metric and reducing associated noise added to a device implementing the associated piezoelectric layer.

In various examples, circuits described herein having such structures can include micro-electroacoustic filters implemented with micro-electromechanical structure (MEMS) technology. MEMS technology includes miniature physical structures that can have both mechanical (e.g., vibrational or acoustic) component characteristics as well as electrical characteristics. In some examples, the resonators described herein can be built using MEMS fabrication techniques to generate structures with dimensions less than one micrometer.

FIG. 4 illustrates an example structure of a modified piezoelectric layer 400 prior to RTA in accordance with aspects described herein. FIG. 4 shows a top-down view of a top surface of a modified piezoelectric layer 400 after an operation replace aluminum (e.g., aluminum atoms) within the AlN crystalline lattice with scandium (Sc). In some cases, scandium may be added to the AlN crystalline lattice using other processes, including, without limitation, sputtering deposition, physical vapor deposition (PVD), pulsed laser deposition (PLD), molecular beam epitaxy (MBE), chemical vapor deposition (CVD), and/or any combination thereof. In one illustrative example, the scandium can be introduced by sputtering deposition. During sputter deposition in accordance with aspects described herein, columnar grains 402 form and grow upwards as the doping operation proceeds. In the view of the modified piezoelectric layer 400 of FIG. 4, most of the columnar grains shown have a cross-sectional width on the order of approximately 30-50 nanometer (nm). As described above, such structures result in increased tanD performance values due to the intersections and electron traps that result as the atom sputtering process produces the columnar grain structure.

FIG. 5A is a chart 500 illustrating aspects of an RTA operation applied to a piezoelectric MEMS device in accordance with aspects described herein. In the example of FIG. 5A, a preheating stage begins at a time T₀. In some aspects, after a pre-determined pre-heating temperature is reached and/or a pre-determined amount of pre-heating time elapses, a modified piezo electric layer sample is rapidly heated beginning at T₁. In some implementations, the heating rate can be between 50 degrees Celsius per second (°C/s) and 200 °C/s. In the illustrative example of FIG. 5A, the heating rate can be equal to 100 °C/s. In some cases, once the target RTA temperature (e.g., 700° C.-1100° C.) is reached at time T₂ the target RTA temperature may be held for a hold duration until time T₃. In the illustrative example of FIG. 5A, the target RTA temperature is 800° C. and the target RTA temperature is held for a duration of 30 s. In some implementations, after time T₃, the sample is allowed to cool.

FIG. 5B illustrates a view of an example structure of a modified piezoelectric layer 510 after RTA in accordance with aspects described herein. The view of the modified piezoelectric layer 510 is at the same scale and perspective as the view of the modified piezoelectric layer 400 of FIG. 4. As illustrated, the RTA process applied to a modified piezoelectric layer 510 provides energy to weaken the grain boundaries between the columnar grains formed by the sputter deposition process. During the RTA, the grains can flow or partially flow together as the energy provided by the RTA causes some grains to reconfigure and material to flow into spaces at grain boundaries. For example, at pointed grain boundaries, material that breaks free from the structure of the grains flows into gaps where the crystalline structures of different grains meet, resulting in an alignment of the grain structures at the intersections as crystals grow together. Adjacent grains thus merge or partially merge due to the RTA process. Such partial merger can result in “neck” structures 512 where intersections between different grains flow together, resulting in larger average grain sizes. In some aspects, a majority of the grains in a modified piezoelectric layer merge or partially merge due to the RTA process. The resulting structure includes more than fifty percent (50%) of columnar grain structures merging or partially merging, and a larger average grain size, grain diameter, or grain width. For example, as illustrated in FIG. 5B, most of the columnar grains shown have a cross-sectional width on the order of 50-70 nm.

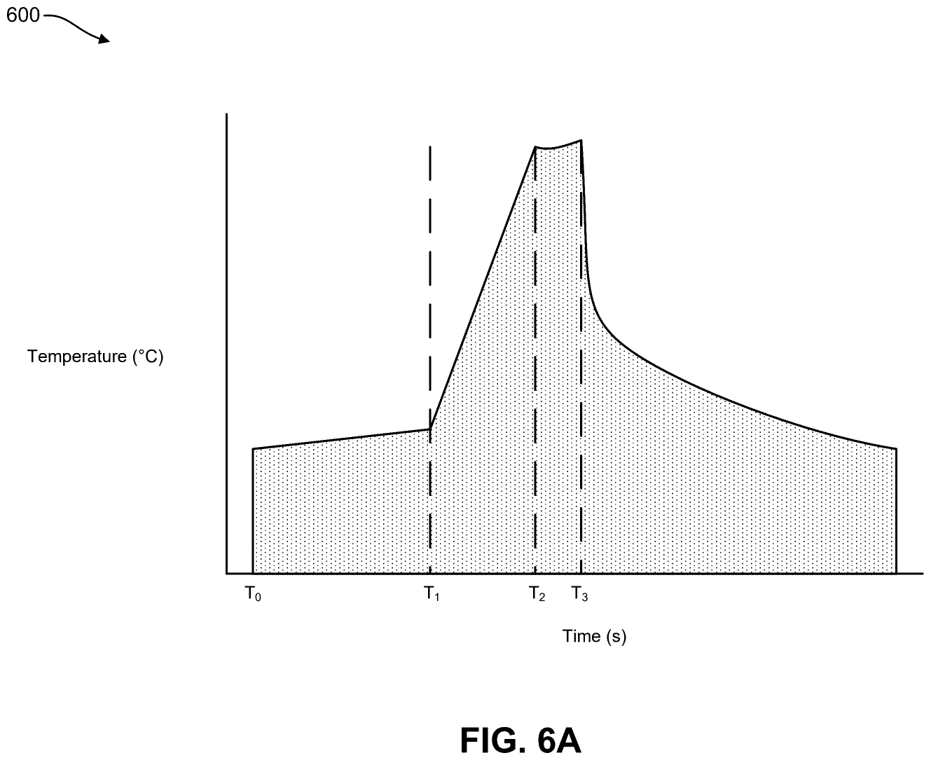

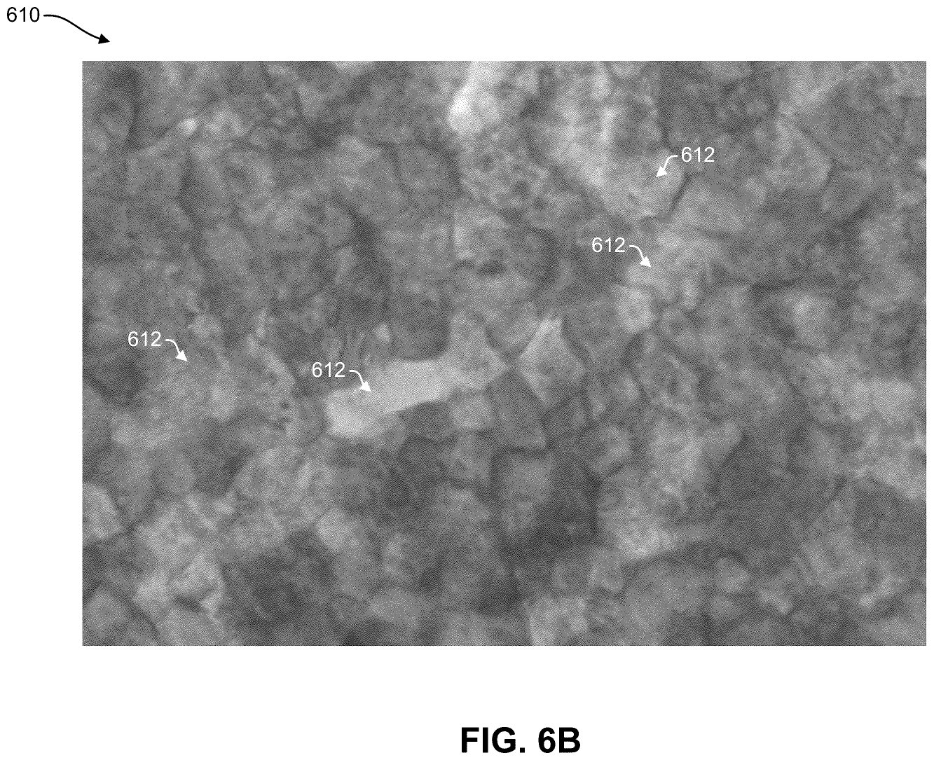

FIG. 6A is a chart 600 illustrating aspects of an RTA operation applied to a modified piezoelectric MEMS device in accordance with aspects described herein. In the example of FIG. 6A, a preheating stage begins at a time T₀. In some aspects, after a pre-determined pre-heating temperature is reached and/or a pre-determined amount of pre-heating time elapses, a modified piezo electric layer sample is rapidly heated beginning at T₁. In some implementations, the heating rate can be between 2 °C/s and 10 °C/s). In the illustrative example of FIG. 6A, the heating rate is 4 °C/s. In some cases, once the target RTA temperature (e.g., 800-1200° C.) is reached at time T₂ the target RTA temperature may be held for a hold duration until time T₃. In the illustrative example of FIG. 6A, the target RTA temperature is 1000° C. and the target RTA temperature is held for a duration of 60 s. In some implementations, after time T₃, the sample is allowed to cool. In one illustrative example, the sample is allowed to cool to 350° C. over a time period greater than 60 s.

FIG. 6B illustrates a view of a modified piezoelectric layer 610 after thermal annealing in accordance with aspects described herein. Similar to the view of the modified piezoelectric layer 510 described above, the modified piezoelectric layer 610 shows an increased number (e.g., relative to the modified piezoelectric layer 400 of FIG. 4 without RTA) of merged grains 612. In the example of FIG. 6B, most of the grains have a grain cross-sectional width on the order of 70 nm and above.

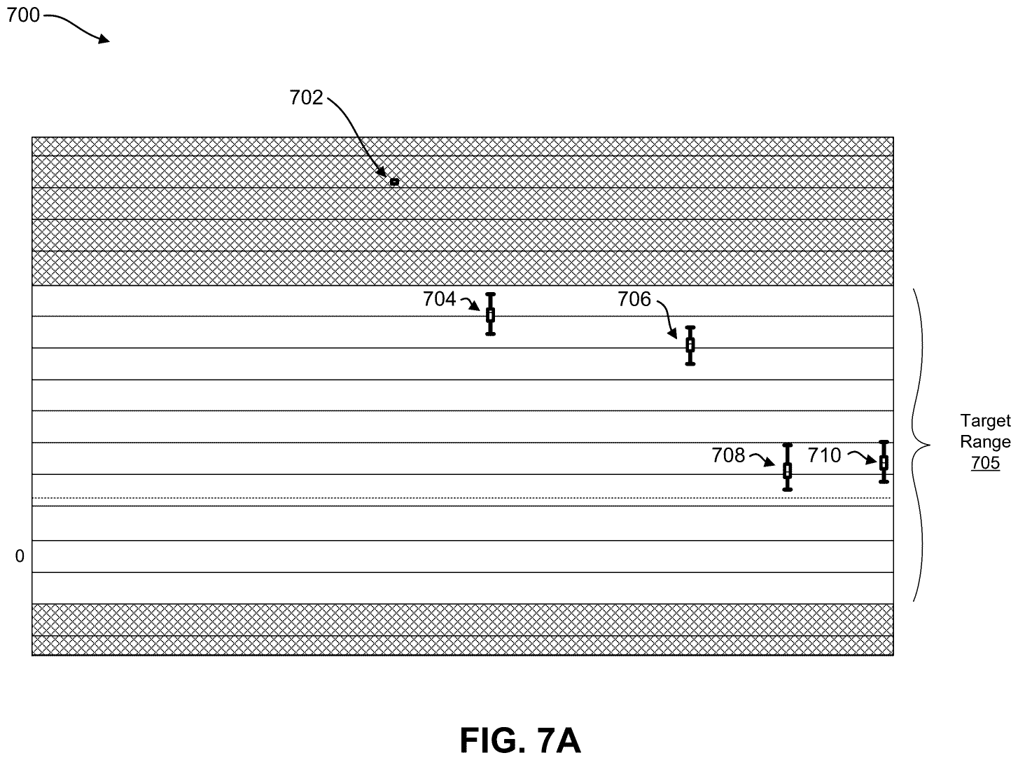

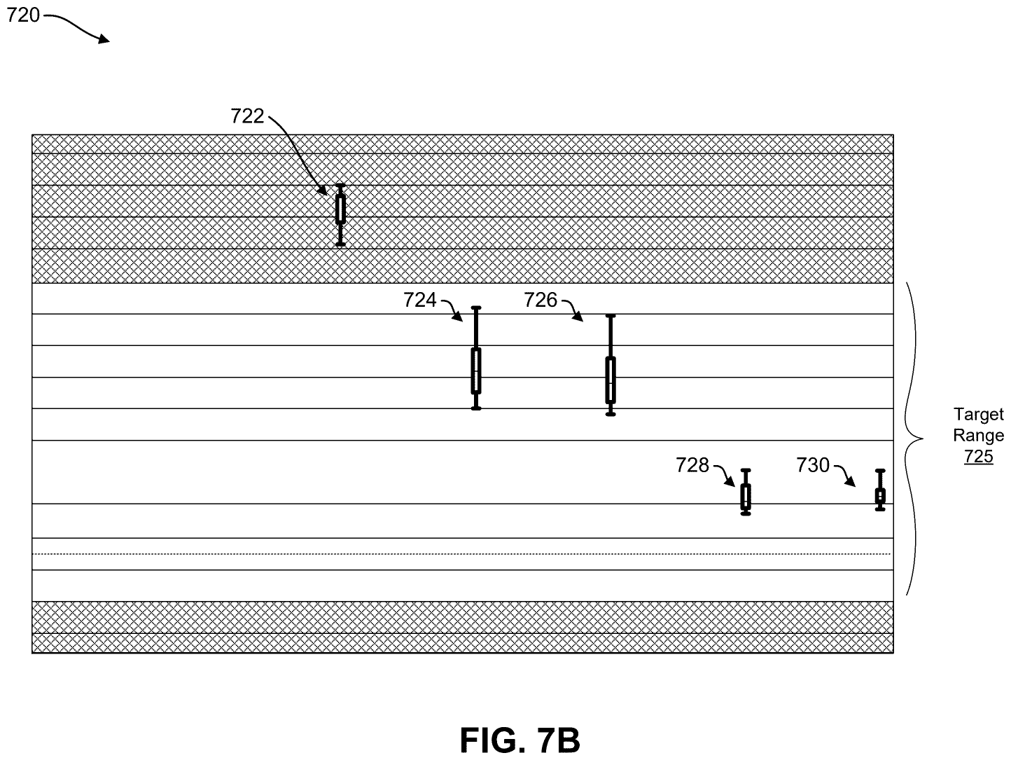

FIG. 7A shows a chart 700 of measured performance values for fabrication of devices having modified piezoelectric layers with and without RTA. The chart 700 has an x-axis with a group split between devices fabricated with no RTA (e.g., error bars 702), devices fabricated with 30 seconds of RTA at 800 degrees Celsius (°C.) (e.g., error bars 704, 706), and devices fabricated with 60 seconds of RTA at 1000 degrees Celcius (°C.) (e.g., error bars 708, 710). The y-axis shows a distribution of tanD values expressed as 10e-6 or parts per million (ppm). The testing results for FIG. 7A may apply to a first modified PZ layer (e.g., modified PZ layer 70 of FIG. 2D) in a multi-layer PZ device, where the first modified PZ layer is sandwiched between two electrode layers (e.g., electrode layer 72, electrode layer 74 of FIG. 2D).

The chart 700 of FIG. 7A shows error bars 702 for devices fabricated without RTA falling outside of a target range 705. The chart 700 also shows error bars 704 and 706 for devices having modified PZ layers subjected to 30 seconds of RTA at 800 degrees Celsius (°C) falling within the target range 705. In addition, the chart 700 shows error bars 708 and 710 for devices having modified piezoelectric layers subjected to 60 seconds of RTA at 1000 degrees Celsius (°C) having further reduced tanD values (e.g., relative to error bars 704, 706) also falling within the target range 705. The tanD values with no RTA (e.g., for error bars 702) when compared to the tanD values with RTA (e.g., for error bars 704, 706, 708, 710) thus show an improvement in the mean tanD value. As described above, a lower tanD value is associated with a lower device contribution to signal noise, and an associated improvement in the overall performance of a device with a component having a lower tanD value.

FIG. 7B shows a chart 720 of measured performance values for fabrication of devices having modified piezoelectric layers with and without RTA. The chart 720 has an x-axis with a group split between devices fabricated with no RTA (e.g., error bars 722), devices fabricated with 30 seconds of RTA at 800 degrees Celsius (°C.) (e.g., error bars 724, 726), and devices fabricated with 60 seconds of RTA at 1000 degrees Celcius (°C.) (e.g., error bars 728, 730). The y-axis shows a distribution of tanD values expressed as 10e-6 or parts per million (ppm). The testing results for FIG. 7B may apply to a second modified PZ layer (e.g., modified PZ layer 80 of FIG. 2D) in a multi-layer PZ device, where the second modified PZ layer is sandwiched between two electrode layers (e.g., electrode layer 86, electrode layer 88 of FIG. 2D).

The chart 720 of FIG. 7B shows error bars 722 for devices fabricated without RTA falling outside of a target range 725. The chart 720 also shows error bars 724 and 726 for devices having modified PZ layers subjected to 30 seconds of RTA at 800 degrees Celsius (°C) falling within the target range 725. In addition, the chart 720 shows error bars 728 and 730 for devices having modified PZ layers subjected to 60 seconds or RTA at 1000 degrees Celsius (°C) having further reduced tanD values (e.g., relative to error bars 724, 726) also falling within the target range 725. The tanD values with no RTA (e.g., error bars 722) when compared to the tanD values with RTA (e.g., error bars 724, 726, 728, 730) thus show an improvement in the mean tanD value. As described above, a lower tanD value is associated with a lower device contribution to signal noise, and an associated improvement in the overall performance of a device with a component having a lower tanD value.

In some cases, further extending the hold time for subjecting devices with modified PZ layers to a non-equilibrium heating process (e.g., RTA) may provide additional benefits to the grain width and lowered tanD values. For example, in some cases, a hold time of 300 s may provide increased grain width and further lowered tanD values when compared to the 30 s and 60 s heating examples described herein.

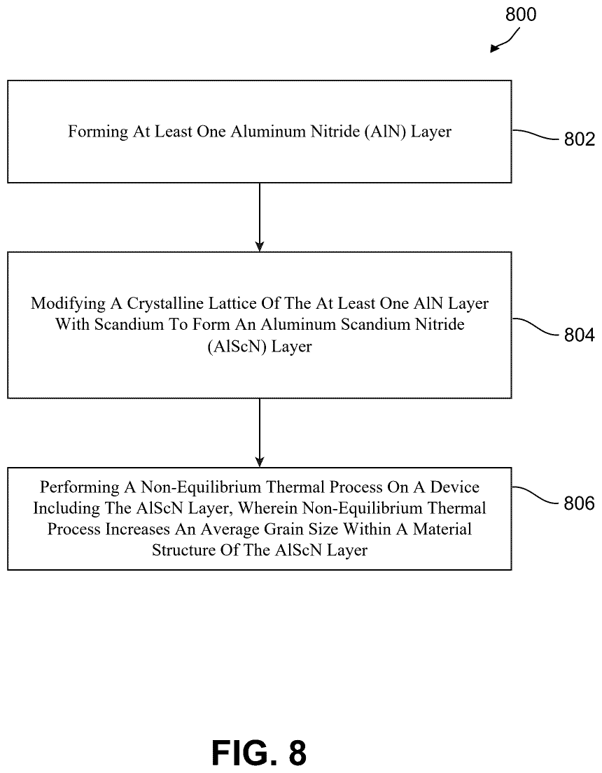

FIG. 8 illustrates a method 800 including operations 802, 804, and 806. At operation 802, the method 800 includes forming at least one AlN layer.

At operation 804, the method 800 includes modifying a crystalline lattice of the at least one AlN layer with scandium to form an AlScN layer.

At operation 806, the method 800 includes performing a non-equilibrium thermal process on a device including the AlScN layer. In some aspects, non-equilibrium thermal process increases an average grain size within a material structure of the AlScN layer.

FIG. 9 is a diagram illustrating an example of a system for implementing certain aspects of the present technology. In particular, FIG. 9 illustrates an example of computing system 900 which can include MEMS transducers or devices including MEMS devices implemented using modified PZ layers subject to RTA in accordance with aspects described herein. An acoustic transducer can be integrated, for example, with any computing device making up internal computing system, a remote computing system, a camera, or any component thereof in which the components of the system are in communication with each other using connection 905. Connection 905 may be a physical connection using a bus, or a direct connection into processor 910, such as in a chipset architecture. Connection 905 may also be a virtual connection, networked connection, or logical connection.

Example computing system 900 includes at least one processing unit (CPU or processor) 910 and connection 905 that communicatively couples various system components including system memory 915, such as read-only memory (ROM) 920 and random access memory (RAM) 925 to processor 910. Computing system 900 may include a cache 912 of high-speed memory connected directly with, in close proximity to, or integrated as part of processor 910.

Processor 910 may include any general purpose processor and a hardware service or software service, such as services 932, 934, and 936 stored in storage device 930, configured to control processor 910 as well as a special-purpose processor where software instructions are incorporated into the actual processor design. Processor 910 may essentially be a completely self-contained computing system, containing multiple cores or processors, a bus, memory controller, cache, etc. A multi-core processor may be symmetric or asymmetric.

To enable user interaction, computing system 900 includes an input device 945, which may represent any number of input mechanisms, such as a microphone for speech or audio detection (e.g., PZ MEMS transducer or a MEMS transducer system in accordance with aspects described above, etc.) along with other input devices 945 such as a touch-sensitive screen for gesture or graphical input, keyboard, mouse, motion input, speech, etc. Computing system 900 may also include output device 935, which may be one or more of a number of output mechanisms. In some instances, multimodal systems may enable a user to provide multiple types of input/output to communicate with computing system 900.

Computing system 900 may include communications interface 940, which may generally govern and manage the user input and system output. The communication interface may perform or facilitate receipt and/or transmission wired or wireless communications using wired and/or wireless transducers, including those making use of an audio jack/plug, a microphone jack/plug, a universal serial bus (USB) port/plug, an Apple™ Lightning™ port/plug, an Ethernet port/plug, a fiber optic port/plug, a proprietary wired port/plug, 3G, 4G, 5G and/or other cellular data network wireless signal transfer, a Bluetooth™ wireless signal transfer, a Bluetooth™ low energy (BLE) wireless signal transfer, an IBEACON™ wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof. The communications interface 940 may also include one or more Global Navigation Satellite System (GNSS) receivers or transducers that are used to determine a location of the computing system 900 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 930 may be a non-volatile and/or non-transitory and/or computer-readable memory device and may be a hard disk or other types of computer readable media which may store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (e.g., Level 1 (L1) cache, Level 2 (L2) cache, Level 3 (L3) cache, Level 4 (L4) cache, Level 5 (L5) cache, or other (L #) cache), resistive random-access memory (RRAM/ReRAM), phase change memory (PCM), spin transfer torque RAM (STT-RAM), another memory chip or cartridge, and/or a combination thereof.

The storage device 930 may include software services, servers, services, etc., that when the code that defines such software is executed by the processor 910, it causes the system to perform a function. In some embodiments, a hardware service that performs a particular function may include the software component stored in a computer-readable medium in connection with the necessary hardware components, such as processor 910, connection 905, output device 935, etc., to carry out the function. The term “computer-readable medium” includes, but is not limited to, portable or non-portable storage devices, optical storage devices, and various other mediums capable of storing, containing, or carrying instructions(s) and/or data. A computer-readable medium may include a non-transitory medium in which data may be stored and that does not include carrier waves and/or transitory electronic signals propagating wirelessly or over wired connections. Examples of a non-transitory medium may include, but are not limited to, a magnetic disk or tape, optical storage media such as compact disk (CD) or digital versatile disk (DVD), flash memory, memory or memory devices. A computer-readable medium may have stored thereon code and/or machine-executable instructions that may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, or the like.

Specific details are provided in the description above to provide a thorough understanding of the embodiments and examples provided herein, but those skilled in the art will recognize that the application is not limited thereto. Thus, while illustrative embodiments of the application have been described in detail herein, it is to be understood that the inventive concepts may be otherwise variously embodied and employed, and that the appended claims are intended to be construed to include such variations, except as limited by the prior art. Various features and aspects of the above-described application may be used individually or jointly. Further, embodiments may be utilized in any number of environments and applications beyond those described herein without departing from the broader scope of the specification. The specification and drawings are, accordingly, to be regarded as illustrative rather than restrictive. For the purposes of illustration, methods were described in a particular order. It should be appreciated that in alternate embodiments, the methods may be performed in a different order than that described.

For clarity of explanation, in some instances the present technology may be presented as including individual functional blocks including devices, device components, steps or routines in a method embodied in software, or combinations of hardware and software. Additional components may be used other than those shown in the figures and/or described herein. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Individual embodiments may be described above as a process or method which is depicted as a flowchart, a flow diagram, a data flow diagram, a structure diagram, or a block diagram. Although a flowchart may describe the operations as a sequential process, many of the operations may be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination may correspond to a return of the function to the calling function or the main function.

Processes and methods according to the above-described examples may be implemented using computer-executable instructions that are stored or otherwise available from computer-readable media. Such instructions may include, for example, instructions and data which cause or otherwise configure a general purpose computer, special purpose computer, or a processing device to perform a certain function or group of functions. Portions of computer resources used may be accessible over a network. The computer executable instructions may be, for example, binaries, intermediate format instructions such as assembly language, firmware, source code. Examples of computer-readable media that may be used to store instructions, information used, and/or information created during methods according to described examples include magnetic or optical disks, flash memory, USB devices provided with non-volatile memory, networked storage devices, and so on.

In some embodiments the computer-readable storage devices, mediums, and memories may include a cable or wireless signal containing a bitstream and the like. However, when mentioned, non-transitory computer-readable storage media expressly exclude media such as energy, carrier signals, electromagnetic waves, and signals per se.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof, in some cases depending in part on the particular application, in part on the desired design, in part on the corresponding technology, etc.

The various illustrative logical blocks, modules, and circuits described in connection with the aspects disclosed herein may be implemented or performed using hardware, software, firmware, middleware, microcode, hardware description languages, or any combination thereof, and may take any of a variety of form factors. When implemented in software, firmware, middleware, or microcode, the program code or code segments to perform the necessary tasks (e.g., a computer-program product) may be stored in a computer-readable or machine-readable medium. A processor(s) may perform the necessary tasks. Examples of form factors include laptops, smart phones, mobile phones, tablet devices or other small form factor personal computers, personal digital assistants, rackmount devices, standalone devices, and so on. Functionality described herein also may be embodied in peripherals or add-in cards. Such functionality may also be implemented on a circuit board among different chips or different processes executing in a single device, by way of further example.

The instructions, media for conveying such instructions, computing resources for executing them, and other structures for supporting such computing resources are example means for providing the functions described in the disclosure.

The techniques described herein may also be implemented in electronic hardware, computer software, firmware, or any combination thereof. Such techniques may be implemented in any of a variety of devices such as general purpose computers, wireless communication device handsets, or integrated circuit devices having multiple uses including application in wireless communication device handsets and other devices. Any features described as modules or components may be implemented together in an integrated logic device or separately as discrete but interoperable logic devices. If implemented in software, the techniques may be realized at least in part by a computer-readable data storage medium including program code including instructions that, when executed, performs one or more of the methods, algorithms, and/or operations described above. The computer-readable data storage medium may form part of a computer program product, which may include packaging materials. The computer-readable medium may include memory or data storage media, such as random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The techniques additionally, or alternatively, may be realized at least in part by a computer-readable communication medium that carries or communicates program code in the form of instructions or data structures and that may be accessed, read, and/or executed by a computer, such as propagated signals or waves.

The program code may be executed by a processor, which may include one or more processors, such as one or more digital signal processors (DSPs), general purpose microprocessors, an application specific integrated circuits (ASICs), field programmable logic arrays (FPGAs), or other equivalent integrated or discrete logic circuitry. Such a processor may be configured to perform any of the techniques described in this disclosure. A general-purpose processor may be a microprocessor; but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Accordingly, the term “processor,” as used herein may refer to any of the foregoing structure, any combination of the foregoing structure, or any other structure or apparatus suitable for implementation of the techniques described herein.

Where components are described as being “configured to” perform certain operations, such configuration may be accomplished, for example, by designing electronic circuits or other hardware to perform the operation, by programming programmable electronic circuits (e.g., microprocessors, or other suitable electronic circuits) to perform the operation, or any combination thereof.

The phrase “coupled to” or “communicatively coupled to” refers to any component that is physically connected to another component either directly or indirectly, and/or any component that is in communication with another component (e.g., connected to the other component over a wired or wireless connection, and/or other suitable communication interface) either directly or indirectly.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, A and B and C, or any duplicate information or data (e.g., A and A, B and B, C and C, A and A and B, and so on), or any other ordering, duplication, or combination of A, B, and C. The language “at least one of” a set and/or “one or more” of a set does not limit the set to the items listed in the set. For example, claim language reciting “at least one of A and B” or “at least one of A or B” may mean A, B, or A and B, and may additionally include items not listed in the set of A and B. The phrases “at least one” and “one or more” are used interchangeably herein.

Claim language or other language reciting “at least one processor configured to,” “at least one processor being configured to,” “one or more processors configured to,” “one or more processors being configured to,” or the like indicates that one processor or multiple processors (in any combination) can perform the associated operation(s). For example, claim language reciting “at least one processor configured to: X, Y, and Z” means a single processor can be used to perform operations X, Y, and Z; or that multiple processors are each tasked with a certain subset of operations X, Y, and Z such that together the multiple processors perform X, Y, and Z; or that a group of multiple processors work together to perform operations X, Y, and Z. In another example, claim language reciting “at least one processor configured to: X, Y, and Z” can mean that any single processor may only perform at least a subset of operations X, Y, and Z.

Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions.

Where reference is made to an entity (e.g., any entity or device described herein) performing functions or being configured to perform functions (e.g., steps of a method), the entity may be configured to cause one or more elements (individually or collectively) to perform the functions. The one or more components of the entity may include at least one memory, at least one processor, at least one communication interface, another component configured to perform one or more (or all) of the functions, and/or any combination thereof. Where reference to the entity performing functions, the entity may be configured to cause one component to perform all functions, or to cause more than one component to collectively perform the functions. When the entity is configured to cause more than one component to collectively perform the functions, each function need not be performed by each of those components (e.g., different functions may be performed by different components) and/or each function need not be performed in whole by only one component (e.g., different components may perform different sub-functions of a function).

A number of implementations have been described. Nevertheless, it will be understood that various modifications may be made without departing from the spirit and scope of the disclosure. Other embodiments are within the scope of the claims.

Illustrative aspects of the disclosure include:

Aspect 1. A device comprising: a support stack comprising a substrate; and a modified piezoelectric layer formed on or above the support stack, wherein the modified piezoelectric layer comprises a material structure modified by non-equilibrium thermal process to increase an average grain size within the material structure of the modified piezoelectric layer.

Aspect 2. The device of Aspect 1, wherein the modified piezoelectric layer comprises an aluminum nitride (AlN) crystalline lattice where at least a portion of aluminum in the AlN crystalline lattice are replaced with scandium forming aluminum scandium nitride (AlScN).

Aspect 3. The device of Aspect 2, wherein the AlN crystalline lattice of the modified piezoelectric layer includes a composition of approximately Al_{0.70} Sc_{0.30} N.

Aspect 4. The device of any one of Aspects 2 or 3, wherein the modified piezoelectric layer comprises columnar grains having an average diameter between thirty (30) and fifty (50) nanometer (nm) after forming the AlScN.

Aspect 5. The device of Aspect 4, wherein at least 10 percent of the columnar grains are at least partially merged following the non-equilibrium thermal process.

Aspect 6. The device of Aspect 5, wherein partial merging of the columnar grains comprises neck structure formation between two columnar grains.

Aspect 7. The device of any one of Aspects 1 to 5, wherein: the device comprises an electroacoustic transducer; and the device comprises a molybdenum layer on or above the substrate.

Aspect 8. The device of Aspect 7, further comprising: a second molybdenum layer formed on or above the modified piezoelectric layer; and an aluminum nitride (AlN) layer formed on or above the second molybdenum layer.

Aspect 9. The device of Aspect 8, further comprising a second modified piezoelectric layer formed between the modified piezoelectric layer and the support stack, wherein the non-equilibrium thermal process further increases an average grain size within a material structure of the second modified piezoelectric layer, and wherein the support stack comprises a first silicon oxide layer, a silicon layer formed on or above the first silicon oxide layer, and a second silicon oxide layer formed on or above the silicon layer.

Aspect 10. The device of any one of Aspects 1 to 9, wherein the device comprises a MEMS microphone, and wherein the support stack and the modified piezoelectric layer is part of a cantilevered piezoelectric beam of a plurality of cantilevered piezoelectric beams of the MEMS microphone.

Aspect 11. The device of any one of Aspects 1 to 10, wherein the device comprises a surface acoustic wave (SAW) transducer, wherein the SAW transducer comprises an interdigitated transducer formed on or above the modified piezoelectric layer.

Aspect 12. The device of any one of Aspects 1 to 11, wherein the non-equilibrium thermal process comprises at least one of application of excimer laser pulses, rastering an electron beam, rastering a laser beam, broad area optical illumination, or rapid thermal annealing.

Aspect 13. A method comprising: forming at least one aluminum nitride (AlN) layer; modifying a crystalline lattice of the at least one AlN layer with scandium to form an aluminum scandium nitride (AlScN) layer; and performing a non-equilibrium thermal process on a device including the AlScN layer, wherein non-equilibrium thermal process increases an average grain size within a material structure of the AlScN layer.

Aspect 14. The method of Aspect 13, wherein performing the non-equilibrium thermal process comprises heating the device from approximately 350 degrees Celsius (°C.) to approximately 800° C. over a first time period, maintaining the device at a temperature of approximately 800° C. over a second time period, and cooling the device from approximately 800° C. to 350° C. over a third time period.

Aspect 15. The method of Aspect 14, wherein the first time period is less than 30 seconds, wherein the second time period is approximately 30 seconds, and wherein the third time period is greater than 60 seconds.

Aspect 16. The method of any one of Aspects 13 to 15, wherein performing the non-equilibrium thermal process comprises heating the device to approximately 1000 degrees Celsius (°C.) over a first time period, maintaining the device at approximately 1000° C. for a second time period, and cooling the device from 1000° C. to less than 300° C. over a third time period.

Aspect 17. The method of Aspect 16, wherein the first time period is less than 180 seconds, the second time period is less than 60 seconds, and wherein the third time period is greater than 60 seconds.

Aspect 18. The method of any one of Aspects 13 to 17, wherein modifying a crystalline lattice of the at least one AlN layer with scandium to form the AlScN layer comprises at least one of sputter deposition, physical vapor deposition (PVD), pulsed laser deposition (PLD), molecular beam epitaxy (MBE), or chemical vapor deposition (CVD).

Aspect 19. The method of any one of Aspects 13 to 18, wherein the non-equilibrium thermal process comprises at least one of application of excimer laser pulses, rastering an electron beam, rastering a laser beam, broad area optical illumination, or rapid thermal annealing.

Aspect 20. A device, comprising: a support stack; and an aluminum scandium nitride (AlScN) piezoelectric layer formed on or above the support stack, wherein the aluminum scandium nitride (AlScN) piezoelectric layer comprises columnar grains and at least 50 percent of the columnar grains are at least partially merged forming neck structure formations between two columnar grains.

Aspect 21: A non-transitory computer-readable storage medium having stored thereon instructions which, when executed by one or more processors, cause the one or more processors to perform any of the operations of aspects 1 to 20.

Aspect 22: An apparatus comprising means for performing any of the operations of aspects 1 to 20.

What is claimed is:

1. A device comprising:
a support stack comprising a substrate; and
a modified piezoelectric layer formed on or above the support stack, wherein the modified piezoelectric layer comprises a material structure modified by non-equilibrium thermal process to increase an average grain size within the material structure of the modified piezoelectric layer.

2. The device of claim 1, wherein the modified piezoelectric layer comprises an aluminum nitride (AlN) crystalline lattice where at least a portion of aluminum in the AlN crystalline lattice are replaced with scandium forming aluminum scandium nitride (AlScN).

3. The device of claim 2, wherein the AlN crystalline lattice of the modified piezoelectric layer includes a composition of approximately Al_{0.70} Sc_{0.30} N.

4. The device of claim 2, wherein the modified piezoelectric layer comprises columnar grains having an average diameter between thirty (30) and fifty (50) nanometer (nm) after forming the AlScN.

5. The device of claim 4, wherein at least 10 percent of the columnar grains are at least partially merged following the non-equilibrium thermal process.

6. The device of claim 5, wherein partial merging of the columnar grains comprises neck structure formation between two columnar grains.

7. The device of claim 1, wherein:
the device comprises an electroacoustic transducer; and
the device comprises a molybdenum layer on or above the substrate.

8. The device of claim 7, further comprising:
a second molybdenum layer formed on or above the modified piezoelectric layer; and
an aluminum nitride (AlN) layer formed on or above the second molybdenum layer.

9. The device of claim 8, further comprising a second modified piezoelectric layer formed between the modified piezoelectric layer and the support stack, wherein the non-equilibrium thermal process further increases an average grain size within a material structure of the second modified piezoelectric layer, and wherein the support stack comprises a first silicon oxide layer, a silicon layer formed on or above the first silicon oxide layer, and a second silicon oxide layer formed on or above the silicon layer.

10. The device of claim 1, wherein the device comprises a MEMS microphone, and wherein the support stack and the modified piezoelectric layer is part of a cantilevered piezoelectric beam of a plurality of cantilevered piezoelectric beams of the MEMS microphone.

11. The device of claim 1, wherein the device comprises a surface acoustic wave (SAW) transducer, wherein the SAW transducer comprises an interdigitated transducer formed on or above the modified piezoelectric layer.

12. The device of claim 1, wherein the non-equilibrium thermal process comprises at least one of application of excimer laser pulses, rastering an electron beam, rastering a laser beam, broad area optical illumination, or rapid thermal annealing.

13. A method comprising:
forming at least one aluminum nitride (AlN) layer;
modifying a crystalline lattice of the at least one AlN layer with scandium to form an aluminum scandium nitride (AlScN) layer; and
performing a non-equilibrium thermal process on a device including the AlScN layer, wherein non-equilibrium thermal process increases an average grain size within a material structure of the AlScN layer.

14. The method of claim 13, wherein performing the non-equilibrium thermal process comprises heating the device from approximately 350 degrees Celsius (°C.) to approximately 800° C. over a first time period, maintaining the device at a temperature of approximately 800° C. over a second time period, and cooling the device from approximately 800° C. to 350° C. over a third time period.

15. The method of claim 14, wherein the first time period is less than 30 seconds, wherein the second time period is approximately 30 seconds, and wherein the third time period is greater than 60 seconds.

16. The method of claim 13, wherein performing the non-equilibrium thermal process comprises heating the device to approximately 1000 degrees Celsius (°C.) over a first time period, maintaining the device at approximately 1000° C. for a second time period, and cooling the device from 1000° C. to less than 300° C. over a third time period.

17. The method of claim 16, wherein the first time period is less than 180 seconds, the second time period is less than 60 seconds, and wherein the third time period is greater than 60 seconds.

18. The method of claim 13, wherein modifying a crystalline lattice of the at least one AlN layer with scandium to form the AlScN layer comprises at least one of sputter deposition, physical vapor deposition (PVD), pulsed laser deposition (PLD), molecular beam epitaxy (MBE), or chemical vapor deposition (CVD) of the scandium to the at least one AlN layer.

19. The method of claim 13, wherein the non-equilibrium thermal process comprises at least one of application of excimer laser pulses, rastering an electron beam, rastering a laser beam, broad area optical illumination, or rapid thermal annealing.

20. A device, comprising:
a support stack; and
an aluminum scandium nitride (AlScN) piezoelectric layer formed on or above the support stack, wherein the aluminum scandium nitride (AlScN) piezoelectric layer comprises columnar grains and at least 50 percent of the columnar grains are at least partially merged forming neck structure formations between two columnar grains.
